(19) United States
(12) Patent Application Publication
(10) Pub. No.: US 2026/0187310 A1
(43) Pub. Date: Jul. 2, 2026

(54) SIMULATION OF AN ELECTRONIC BLOCK

(71) Applicant: SRI International, Menlo Park, CA (US)

(72) Inventors: John Byrnes, Poway, CA (US); Mike Piacentino, Hamilton, NJ (US); David Zhang, Belle Mead, NJ (US); Indhumathi Kandaswamy, Yardley, PA (US); Gooitzen van der Wal, Hopewell, NJ (US)

(21) Appl. No.: 18/761,144

(22) PCT Filed: Apr. 17, 2023
(86) PCT No.: PCT/US2023/018858

§ 371 Date: Jul. 1, 2024

Related U.S. Application Data
(60) Provisional application No. 63/332,053, filed on Apr. 18, 2022.

(51) Int. Cl. G06F 30/27

(52) U.S. Cl. CPC G06F 30/27

(57) ABSTRACT

A model generator receives inputs of formal descriptions of an expected behavior of an electronic block. The model generator generates one or more models. Each generated model has a deep learning architecture to simulate an electronic block based upon the formal descriptions of an expected behavior of the electronic block. The model generator can then train each model with the deep learning architecture to simulate the electronic block using the formal descriptions of an expected behavior of that electronic block as logical reasoning to constrain machine learning of that model from training data during training of that model to simulate the electronic block to be consistent with the logical reasoning.

### CROSS-REFERENCE

This application claims priority under 35 USC 119 to U.S. provisional patent application Ser. 63/332,053 titled “DASL FOR SIMULATING DIGITAL CIRCUITS,” filed 18 Apr. 2022, which the disclosure of such is incorporated herein by reference in its entirety.

### TECHNICAL FIELD

Embodiments of this disclosure relate generally to artificial intelligence.

### BACKGROUND

Electronic design automation can use many verification methodologies. Universal Verification Methodology (UVM) is an industry standard for verifying the correctness of digital circuit designs. In a typical development cycle, a design will be specified using a hardware assertion language such as Verilog. Much of the development is done at the Register Transfer Level (RTL), which captures the transfer of bit values between registers. RTL simulation involves simulating the clock that synchronizes communication within the electronic circuit but is at a higher level of abstraction than gate level simulation, which simulates the settling time of the gates. Devices coded in RTL, for complex systems, these simulations are very slow but very precise. The simplest testing of a novel/new electronic circuit tests the electronic circuit in isolation, but more elaborate testing requires simulating the entire system of other devices/components with which the novel/new electronic circuit being designed will interact in the electronic design automation environment.

Testing is currently very time consuming and stands as an impairment to the rapid development of novel microelectronic systems. Commercial developers spend large amounts of money on custom hardware to speed up testing. Systems that have a fairly small market, suffer from long development times that slow innovation and raise costs significantly. Any speedups in the testing process, especially those that come at low cost, provide for more rapid innovation and lower costs for defense systems and for commercial microelectronic devices.

### SUMMARY

Provided herein are various methods, apparatuses, and systems that use an artificial intelligence architecture.

In an embodiment, a model generator with one or more inputs receives inputs of formal descriptions of an expected behavior of an electronic block. The model generator generates one or more models. Each generated model has a deep learning architecture to simulate an electronic block based upon the formal descriptions of an expected behavior of the electronic block. The electronic block can be any of i) an electronic component, ii) an electronic circuit, iii) an electronic subsystem, iv) a system on a chip, and v) an integrated circuit chip.

The model generator can train each model with the deep learning architecture to simulate the electronic block using the formal descriptions of an expected behavior of that electronic block as logical reasoning to constrain machine learning of that model from training data during training of that model to simulate the electronic block to be consistent with the logical reasoning.

The model generator and its generated one or more models that have been trained to simulate corresponding specific electronic blocks can cooperate with an electronic design automation tool.

These and many more embodiments are discussed.

### DRAWINGS

FIGS. 1a and 1b illustrate block diagrams of an embodiment of example stages used by a model generator to generate one or more models that each have a deep learning architecture to simulate a corresponding electronic block;

FIG. 2 illustrates block diagrams of an embodiment of an example model generator to generate one or more models that each have a deep learning architecture to simulate a corresponding electronic block based upon the formal descriptions of the expected behavior of the electronic block;

FIGS. 3a and 3b illustrate block diagrams of an embodiment of a model generator using training data and formal descriptions of the expected behavior of the electronic block going into an example model simulating an electronic block;

FIG. 3c illustrates an embodiment of the model generator using an example formal description of the expected behavior of the electronic block constraining the training of the model simulating the simple circuit being described in FIGS. 3a and 3b.

FIG. 4 illustrates a block diagram of an embodiment of an example model generator that has one or more inputs configured to receive inputs of formal descriptions of the expected behavior of that electronic block, written in a hardware assertion language in a format that an automated assertion checker tool can understand to be used as logical reasoning to constrain machine learning of that model from training data during training of that model to simulate the electronic block to be consistent with the logical reasoning;

FIGS. 5a and 5b illustrate block diagrams of an embodiment of an example electronic design automation tool configured to test and verify a device under test in a system containing the device under test and the electronic blocks to be simulated by the models generated by the model generator;

FIG. 6 illustrates a block diagram of an embodiment of an example model having a deep learning architecture to simulate an electronic block of a round robin Arbiter; and

FIG. 7 illustrates a diagram of an embodiment of a computing device that can be a part of the systems associated with the device and its associated modules and the machine learning architecture discussed herein.

While the design is subject to various modifications, equivalents, and alternative forms, specific embodiments thereof have been shown by way of example in the drawings and will now be described in detail. It should be understood that the design is not limited to the particular embodiments disclosed, but—on the contrary—the intention is to cover all modifications, equivalents, and alternative forms using the specific embodiments.

### DESCRIPTION

In the following description, numerous specific details can be set forth, such as examples of specific data signals, named components, number of frames, etc., in order to provide a thorough understanding of the present design. It will be apparent, however, to one of ordinary skill in the art that the present design can be practiced without these specific details. In other instances, well known components or methods have not been described in detail but rather in a block diagram in order to avoid unnecessarily obscuring the present design. Further, specific numeric references such as the first server, can be made. However, the specific numeric reference should not be interpreted as a literal sequential order but rather interpreted that the first server is different than a second server. Thus, the specific details set forth can be merely exemplary. The specific details can be varied from and still be contemplated to be within the spirit and scope of the present design. The term “coupled” is defined as meaning connected either directly to the component or indirectly to the component through another component.

The model generator can have three main aspects. 1) The model generator composes and generates a model with a deep learning architecture based upon formal descriptions of an expected behavior of that electronic block. 2) The model generator trains the model with the deep learning architecture to simulate the electronic block using the formal descriptions of an expected behavior of that electronic block as logical reasoning to constrain machine learning of that model from training data during training of that model to simulate the electronic block. 3) The generated and trained models from the model generator then are utilized with a simulation tool and/or other electronic design automation tool as a design aid in the testing and verification of a new electronic design/device.

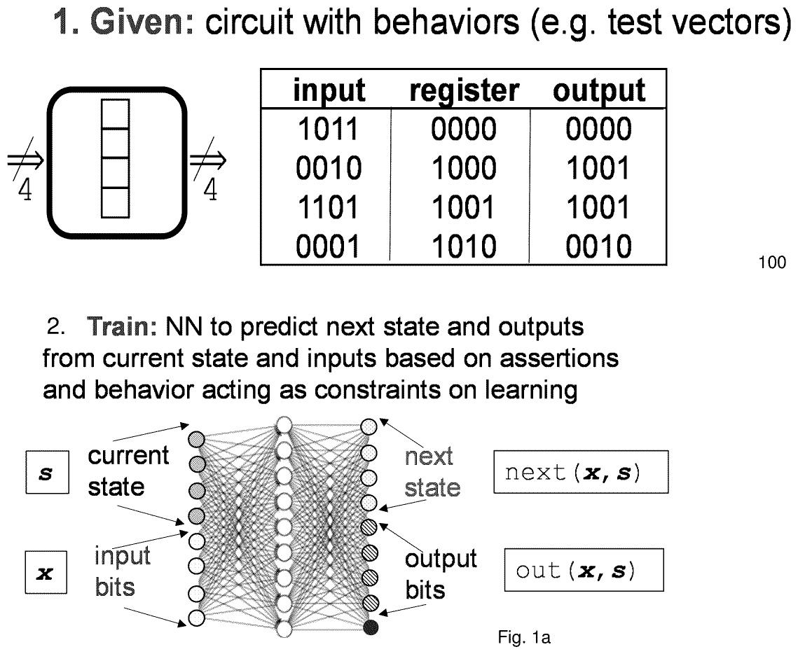

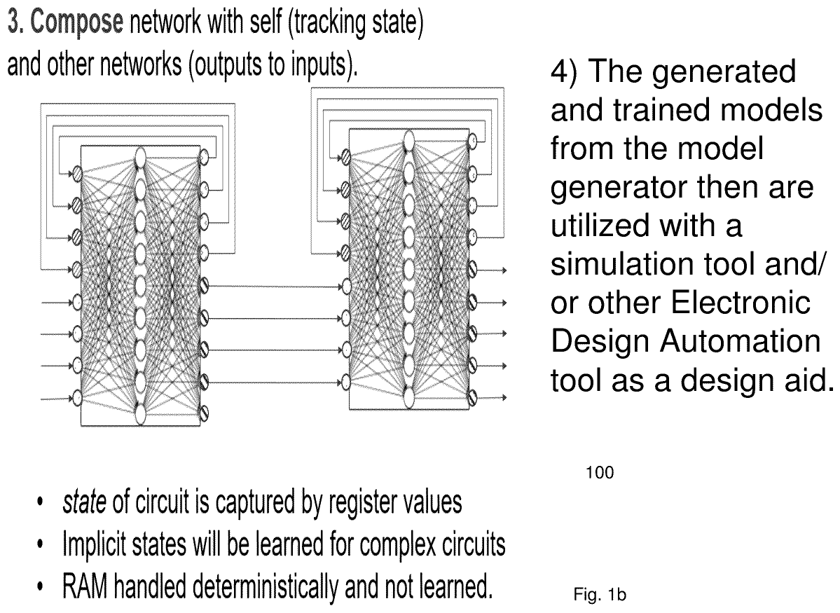

FIGS. 1a and 1b illustrate block diagrams of an embodiment of example stages used by a model generator to generate one or more models that each have a deep learning architecture to simulate a corresponding electronic block.

The model generator 100 uses at least four steps to generate a model with a deep learning architecture that is trained to simulate an electronic block. 1) The model generator 100 can be supplied with information and/or import features and characteristics of an electronic block and its expected behaviors (e.g. test vectors). 2) The model generator 100 can then construct/compose a deep learning architecture with inputs and outputs, such as a neural network, structured on expert knowledge. The model generator 100 can compose the deep learning architecture with self-tracking states for each network, and with inputs and outputs to other networks within the deep learning architecture. 3) The model generator 100 can then train the deep learning architecture based on empirical data. The model generator 100 can train the deep learning architecture to predict a next state and outputs from a current state and inputs based on assertions and behavior acting as constraints on the machine learning that occurred for that deep learning architecture. The state of the circuit can be captured by register values. Implicit states can be learned for complex circuits. Pure memory/storage of data can be handled deterministically and not learned. Note, deep learning primarily uses neural networks (e.g., CNN, RNN, Transformer, etc.), but could it be any machine architecture with a gradient optimization (e.g. a regression model) that is capable of simulating the functions and behavior of the electronic blocks (e.g. electronic components and electronic circuits).

The model generator 100 trains the model with a deep learning architecture to simulate an electronic block such as i) an electronic component, ii) an electronic circuit, iii) an electronic subsystem, iv) a system on a chip, and v) an integrated circuit chip. 4) The generated and trained models from the model generator 100 then are utilized with a simulation tool and/or other EDA tool as a design aid in the testing and verification of a new electronic design/device. For example, the generated and trained models from the model generator 100 are used during the testing and verification of a Design Under Test (DUT) with the trained model to supply some of the functionality other components in the system that includes the DUT.

In an example, each constructed deep learning architecture (e.g. neural network) is designed, constructed, and trained to simulate an individual electronic component within a system being used in testing and verification of a device under test in an EDA testing environment.

In an example stand-alone verification process, a new DUT is simulated at the Register Transfer Level (RTL). Test inputs are generated and provided to the simulated DUT, which generates outputs that can be compared to the desired outputs. Once a DUT passes the stand-alone tests, system-level testing begins, in which the simulated DUT is run in the context of a simulation of the full system that it will interact with. This previously required RTL simulation of all components of this system including the DUT, even though most of these components may already be thoroughly tested as known, mature available devices that are in common use in the market. Simulating these known, mature available devices (e.g. electronic blocks) is very time consuming, and long runs are required in order to generate sufficient coverage of system states. The model generator 100, such SRI International's Deep Adaptive Semantic Logic (DASL) 3rd wave neurosymbolic platform, can perform a fast simulation of these known, mature, available devices. An example of the electronic block that the model generated by the model generator 100 is a known, mature, available device.

The model generator 100 can generate the deep learning architecture (e.g. neural networks) to simulate electronic blocks while also addressing simulating one or more components (e.g. electronic blocks) of this system working with the DUT. The model generator 100 can generate the deep learning architecture in each model to simulate a corresponding electronic block (e.g. known, mature, available device) even when a full architecture of the components making up the electronic block is not available, that is, when the model generator 100 may have access merely to behavioral specifications of the electronic block but not to a full specification of the electronic block itself. Thus, the model generator 100 is configured to construct the deep learning architecture (e.g. neural networks) to simulate the electronic block based on the formal descriptions of the expected behavior (e.g. formal specification and/or test vectors) rather than needing a formal specification on a full architecture making up that electronic block (e.g. electronic component and/or electrical circuit). Thus, the model generator constructs the deep learning architecture to simulate the electronic block based on the formal descriptions of the expected behavior rather than needing a formal specification of a full architecture making up the electronic block, which causes a verification of a device under test to occur in less time than the verification of the device under test would take with the full architecture making up the electronic block. The model generator 100 requires the input of the formal descriptions of the expected behavior in order to learn its intended functions to be performed during a subsequent simulation testing and verifying the DUT in conjunction with these generated models simulating other electronic blocks in the system.

The model generator 100 can generate neural networks that are capable of being trained from RTL data to simulate electronic blocks, provide a significant speedup over RTL simulations in standard verification frameworks, and learn from small data sets when complemented with the formal descriptions of the expected behavior.

Writing custom simulators for every new IC chip to operate on larger transactions can be avoided by the model generator 100 generating a deep learning architecture, such as a neural network, simulating an electronic block and then training the neural network to simulate the behavior and functions of the electronic block based on, for example, data generated by existing RTL simulators. This can be done with reasonable accuracy given a sufficient amount of training data, but this data of course takes time to generate. In order to minimize the required amount of data (and therefore the amount of RTL data generation time), the model generator 100 can use formalized knowledge, as in Formal Methods, to supplement data and constrain learning from that training data.

Next, System Verilog Assertions (SVA) provide an example way of a hardware assertion language supplying formalized knowledge of the behavior of an electronic block. Property Specification Language (PSL) is another example formal hardware assertion language that captures temporal logic and is often used to specify system behavior requirements. While these requirements do not usually specify a unique algorithm, they do greatly narrow the space of possible algorithms consistent with a set of training data.

The model generator 100 can use one or more deep learning architectures (e.g., neural networks) to simulate one or more electronic blocks in the system being tested with the DUT, where at least the DUT and optionally one or more of the other electronic blocks in the system being tested with the DUT are coded in RTL. The remainder of the electronic blocks in the system being tested with the DUT will be generated models from the model generator 100 that have been trained to simulate that specific electronic block, and can be coded in, for example, C. The EDA testing environment can use combinations of blocks, including 1) the DUT coded in RTL and 2) the electronic blocks created to perform AI simulation, but of course, the runtimes are dominated by the RTL simulations.

The model generator 100 can, for example, use neural network simulation of digital circuits to speed up an amount of time required to test new microelectronic systems while still in the design stage while maintaining current high levels of the design validation. The neural networks simulating sets of electronic blocks while testing a DUT in an EDA environment can speed up the testing time by at least 1000 times (e.g. 12,000×) in configurations with large computation requirements. In general, the neural networks are fast enough that system overheads dominate the runtime during the simulations, but the model generator 100 does still speedup the process over 1,000×.

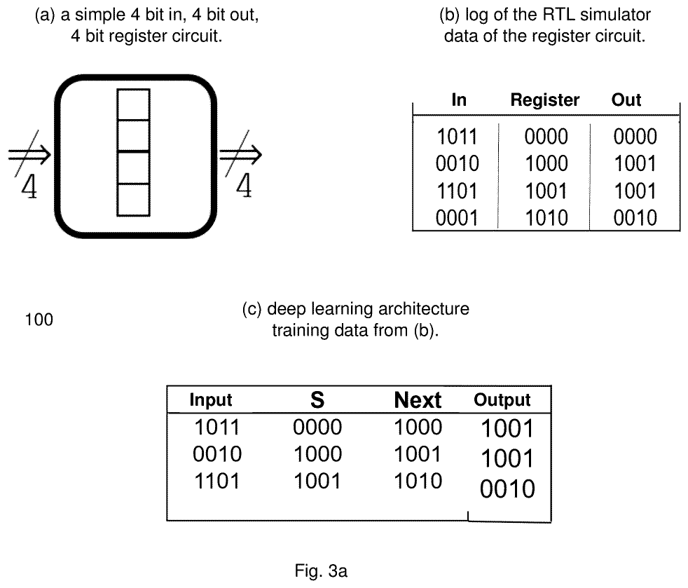

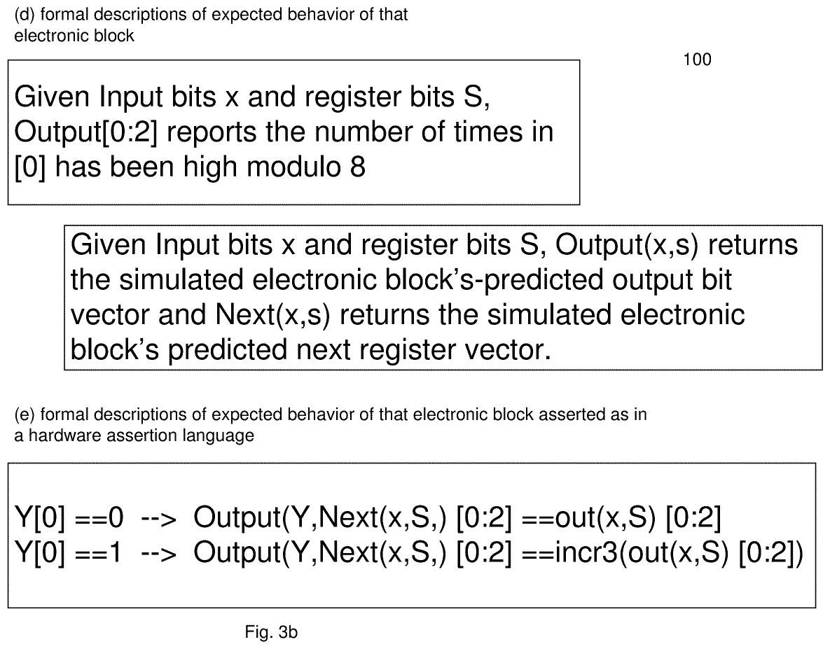

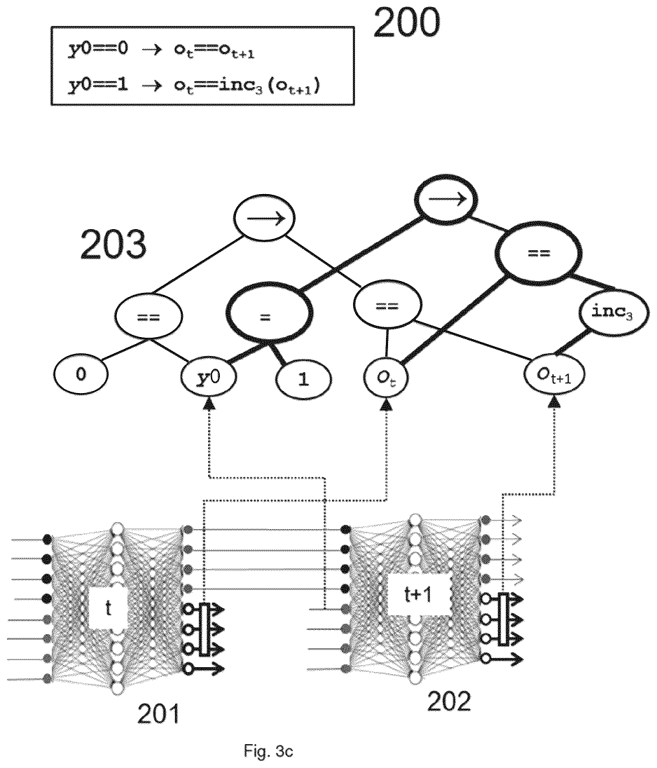

Testing a DUT in an EDA environment with neural networks simulating sets of electronic blocks supports arbitrary combinations of RTL and AI simulation, where the runtimes are dominated by the RTL simulations. The model generator 100 uses System Verilog Assertions and other formal descriptions of circuit behavior as logical reasoning embedded into a training of a model in order to reduce the training data requirements for training the model simulating the electronic block. The hardware assertion language, such as Verilog, PSL, etc. allows a formal way of expressing logical reasoning in manner understandable by an automated assertion checker tool (e.g. simulation tool) running the EDA environment. The formal descriptions of the expected behavior from, for example, human expert knowledge (e.g. see FIG. 3b steps (d) and/or (e)) is used as logical rules/reasoning for the electronic block written in a hardware assertion language in a format which an automated assertion checker tool (e.g. simulation tool) can understand (the Verilog assertions, PSL assertions, etc.) System Verilog Assertions are essentially a language construct which provides a powerful way to write formal assertions such as constraints, checkers, and cover points as these rules for the electronic block. It lets you express rules (i.e., English sentences) in the design specification in a SystemVerilog format which, then automated assertion checker tools can understand.

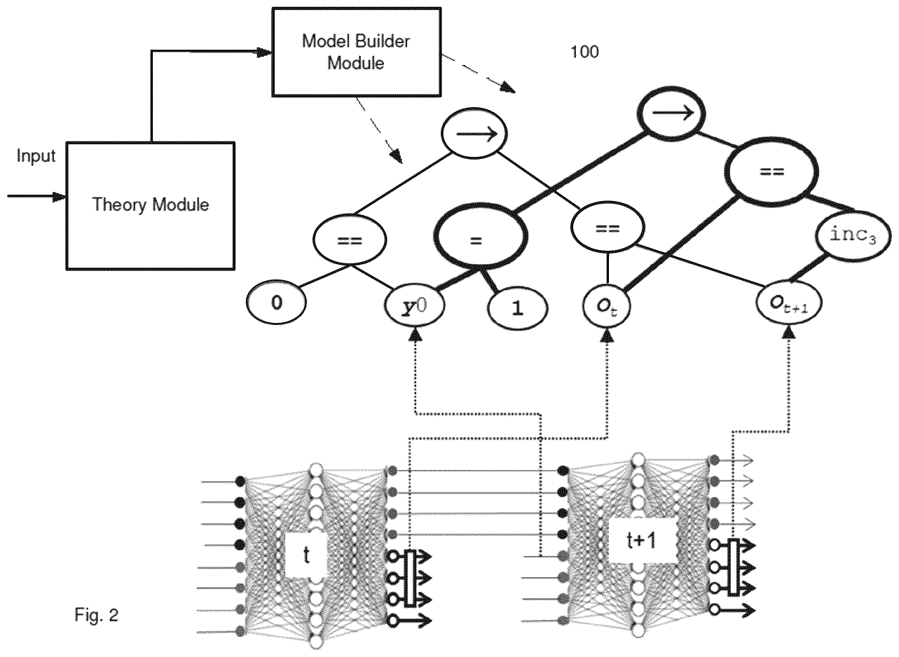

FIG. 2 illustrates block diagrams of an embodiment of an example model generator to generate one or more models that each have a deep learning architecture to simulate a corresponding electronic block based upon the formal descriptions of the expected behavior of the electronic block.

The model generator 100 has one or more inputs configured to receive inputs of the formal descriptions of the expected behavior of an electronic block.

The model generator 100 can have a theory module configured to encode and send the formal descriptions of the expected behavior of that electronic block to be turned into scientific language of the expected behavior comprehensible to computational algorithms by cooperating with other modules in the model generator 100. The theory module can receive as input the formal descriptions of the expected behavior of that electronic block expressed in first order logic elements and then encode and send the encoded formal descriptions of the expected behavior of that electronic block to a model building module in the model generator to use machine learning to discover distributed vector representations of a meaning associated with information (e.g. terminology, formula, etc.) stated in the formal descriptions of the expected behavior and generate the deep learning architecture. The model generator 100 can be the 3rd wave SRI DASL artificial intelligence (AI) platform or other similar AI model generator 100. Example details of one possible implementation of a platform capable of generating Artificial Intelligence models can be found in US patent application titled “Neural-symbolic computing,” application Ser. No. 17/283,502, filing date 7 Apr. 2021, incorporated herein by reference in its entirety.

The model generator 100 can receive an input of the formal descriptions of the expected behavior of that electronic block as logical reasoning to guide a training of that model, where the formal descriptions of the expected behavior of that electronic block is a specification, test vectors, etc., for the electronic block and supplied into the model generator 100. The theory module is coded to encode and send the expected behavior to be turned into first order logic elements to make formal scientific language comprehensible to computational algorithms by cooperating with the other modules to use machine learning to discover distributed vector representations of a meaning associated with the terminology. The created neural networks will have multiple layers. The resulting model generated by the model generator 100 is inherently composable, as each concept of the asserted formal knowledge is modeled in the dedicated deep learning architecture (e.g. neural network), and these networks are automatically assembled to form the composite concepts expressed in the formal knowledge.

In an example, the model generator 100 can initially generate and train simple multi-layer perceptrons (MLPs e.g. neural networks with at least three layers) with a few hidden layers to learn to behaviors of the smallest blocks and then can compare performance on held-out data not seen during training time to performance on training data. This will allow the model generator 100 to measure over-training and under-training as a function of the number of network parameters and the number of input, output, and register bits. If the MLPs are insufficient to capture the behavior of basic blocks, the model generator 100 will next explore embedding states for register values and attention-based models to determine which outputs and which next states depend on which inputs and current states. The model generator 100 collects this information and can generate a report on training accuracy and validation accuracy of models explored as a function of block complexity and the number of network parameters.

In an example, in order to avoid vanishing gradients, the model generator 100 can use rectified linear unit (ReLU) activation functions. The model generator 100 can experiment with both ReLU and ELU (the “exponential linear unit”) for input activations under some training regimes. The model generator 100 when composing the model can compromise between the explosive growth of the nested linear layers and the vanishing gradients of the nested sigmoid layers.

The model generator 100 creates accurate surrogate models with a deep learning architecture to simulate electronic blocks, such as integrated circuits (ICs), that operate over 1000 times faster than standard RTL simulators, reducing total test time (including final full RTL simulation) by a factor greater than 10. The model generator 100 combines knowledge representations with AI learning capabilities, enabling machine learning to constrain its learning to be consistent with the formal asserted knowledge. The formal descriptions of the expected behavior enable meta-cognition, as the model generator 100 uses the knowledge to assess its treatment of unlabeled data, such as test vectors that were not provided for learning. Self-training using the asserted formal knowledge, the formal descriptions of component behavior/circuit behavior (e.g. specifications and/or test vectors) will allow the model that has a deep learning architecture to simulate an electronic block to achieve over 90% accuracy without requiring additional RTL simulation.

FIGS. 3a and 3b illustrate block diagrams of an embodiment of a model generator using training data and formal descriptions of the expected behavior of the electronic block going into an example model simulating an electronic block.

In this example, the model generator 100 takes the initial steps (a)-(e) to compose and train an example model simulating an electronic block. (a) The electronic block being modeled by the deep learning architecture (e.g. neural network) named NN is a simple 4 bit in, 4 bit out, 4 bit register circuit. (b) The log of RTL simulator training data/test vectors that is run on the register circuit (a). This is a logging of all of the bits put in, registered, and bits out at each clock cycle of the RTL simulation. (c) The input and register values at each cycle that will be Input as training data/test vectors to train the deep learning architecture (e.g. neural network), which will predict the register value and output values at the next cycle as its Output. The training data/test vectors are the variables in the network. (d) The formal descriptions of the expected behavior of that electronic block are used as a logical rule/reasoning. The example expected behavior of that electronic block used as logical reasoning can be “Given Input bits x and register bits S, Output[0:2] reports the number of times in [0] has been high modulo 8.” “Given Input bits x and register bits S, Output(x,s) returns the simulated electronic block's-predicted output bit vector and Next(x,s) returns the simulated electronic block's predicted next register vector.” (e) The formal descriptions of the expected behavior of that electronic block used as the logical rule/reasoning provided from (d) are asserted as in a hardware assertion language in the model generator 100.

The logic of the model generator 100 restricts the deep learning architecture (e.g. neural networks) to learn behavior consistent with the specified behavior/function of the electronic block being simulated e.g. register circuit. The behavior intended to be learned can be formalized in the hardware assertion language as a System Verilog Assertion. Thus, the constructed deep learning architecture (e.g. NN1 and NN2) is configured to learn from the training data constrained by the formal descriptions of the expected behavior of that electronic block as the logical reasoning to constrain the learning of that model during training to simulate the electronic block to be consistent with the logical reasoning.

The example formal descriptions of the expected behavior of that electronic block used as a logical reasoning provided from (d) are asserted as in a hardware assertion language. For example, a hardware assertion could be:

$$Y [ 0 ] == 0 \text{-->} Output ( Y , Next ( x , S , ) [ 0 : 2 ] == out ( x , S ) [ 0 : 2 ]$$

$$Y [ 0 ] == 1 \text{-->} Output ( Y , Next ( x , S , ) [ 0 : 2 ] == incr 3 ( out ( x , S ) [ 0 : 2 ] )$$

Where ‘-->’ is the Boolean IF-THEN operator and ‘==’ is a binary operator testing equality. Both are continuous and output 1 when satisfied exactly, 0 when violated as strongly as possible, and intermediate values otherwise. Both are differentiable to enable learning. The model generator 100 can implement an increment operator with rollover. In addition, given input bits x and register bits S, out(x,s) returns the simulated electronic block's predicted output bit vector and Next(x,s) returns the simulated electronic block's predicted next register vector. Where y[0] indicates the 0th (rightmost and least significant) bit of y; y[0:2] indicates bits 0 through 2 (inclusive). Incr3(x) returns x+1, given 3-bit vector x, rolling over on overflow.

The example deep learning architecture of the register circuit in the model is trained 1) to produce training outputs when given training inputs from (c); and 2) to satisfy assertions (e) for arbitrary inputs. The generated and trained model from the model generator 100 emulates the electronic block (a) (e.g. 4-bit register circuit) by predicting the output on the next clock cycle given the input on the current cycle. Because the electronic block will generally be stateful, the output is a function both of the current input and the current register values (which capture the state). The deep learning architecture must also predict the next state in order to emulate the electronic block. In this example, the formal descriptions of the expected behavior of that electronic block used as the logical rule/reasoning provided from (d) is asserted as in a hardware assertion language out and next in (e) are functions which are implemented by the neural network. Note, the model generator 100 can implement differentiable versions of many operators to accommodate most concepts needed to be asserted.

The model generator 100 constructs the deep learning architecture structured on formal descriptions of the expected behavior of that electronic block supplied as an input into the model generator 100 and then trains the deep learning architecture based on empirical training data. The model generator 100 is configured to train the deep learning architecture to a threshold accuracy that agrees (e.g. 98% accuracy) with the formal descriptions of the expected behavior of that electronic block with a mixture of labeled training data examples unlabeled training data examples during the training to simulate the specific electronic block.

The example electronic block of the register circuit neural networks outputs continuous values between 0 and 1 and learns by backpropagating the error in its prediction. Each assertion in the model generator 100 constructs a new AI network which has a correct output value of 1 (indicating that the assertion is True). All constructors in the assertions in the model generator 100 are differentiable, so that when an output other than 1 is generated, the error signal can be backpropagated just as in normal AI network training.

Memory Representation. The model generator 100 implements memory storage separately from the neural networks so that memory storage can be emulated without being learned. Some of the registers within the electronic block (a) register circuit will be used as simple memory storage. These may contain a very large number of bits, and the models generated by the model generator 100 will not use neural representations to compute them, but rather can simply maintain a memory for reading and writing. The engineer can indicate memory registers to the model generator 100 in the same way that they are indicated to the RTL simulator to avoid logging on every cycle.

Abstract State. The behavior of any electronic block depends on its state, and the state of any circuit is captured by its register values. For the very simple electronic block in FIGS. 3a and 3b, the model generated by the model generator 100 can emulate the register values directly. This may be practical for many electronic blocks, as neural networks with several million parameters are common and train fairly quickly. However, in some examples, it will likely be the case that complex blocks will have too many bits of registers to emulate exactly. In this case, the deep learning architecture will learn to generate abstract state vectors from register values and will learn to predict state vectors rather than register values. Outputs will also depend on state vectors. These state vectors will be “embeddings” of the register values, a technique familiar in machine learning from natural language processing such as word2vec. These same techniques have been most recently developed into Transformer models, which learn to score the amount of “attention” that each available input should be given when computing each given output. The model generator 100 can use, for example, artificial intelligence transformers for some applications for electronic block emulation.

FIG. 3c illustrates an embodiment of the model generator using an example formal description of the expected behavior of the electronic block constraining the training of the model simulating the simple circuit being described in FIGS. 3a and 3b. The example formal description of the expected behavior of the electronic block expressed with first order logic from FIG. 3e is displayed in box 200 using abbreviations for convenience: y0 for y[0], oₜ for the first 3 bits of output of the circuit at time step t, oₜ₊₁ for the first 3 bits of output of the circuit at time step t+1, and inc₃ for the 3-bit increment function (counting mod 8). The example neural networks making up the deep learning architecture 201 displays the first neural network at time t and 202 displays the second neural network at time t+1. The state bit flows from the first neural network 201 to the second neural network 202, while the input and output bits of neural networks 201 and 202 are not connected. The example formal description of the expected behavior of the electronic block expressed with first order logic 200 (e.g.):

$$y 0 == 0 \to {o}_{t} == {o}_{t + 1}$$

$$y 0 == 1 \to {o}_{t} == {inc}_{3} ( {o}_{t + 1} )$$

The example formal description of the expected behavior of the electronic block from 200 is represented by the model builder module in the network 203. y0, ot, and ot+1 are obtained from the NN inputs and outputs. The nodes ‘0’ and ‘1’ represent constant bit values. The thinner lighter tree is the parse tree of the first assertion in box 200 and the thicker darker tree is the parse tree of the second assertion in box 200. The top of the network has 2 outputs: one is the truth value of the first assertion Oₜ and the other is the truth value of the second assertion Oₜ₊₁, for any given time step and set of inputs and outputs from the trained network. The model generator trains a generated network until the generated network produces the value “true” for both assertions at all times.

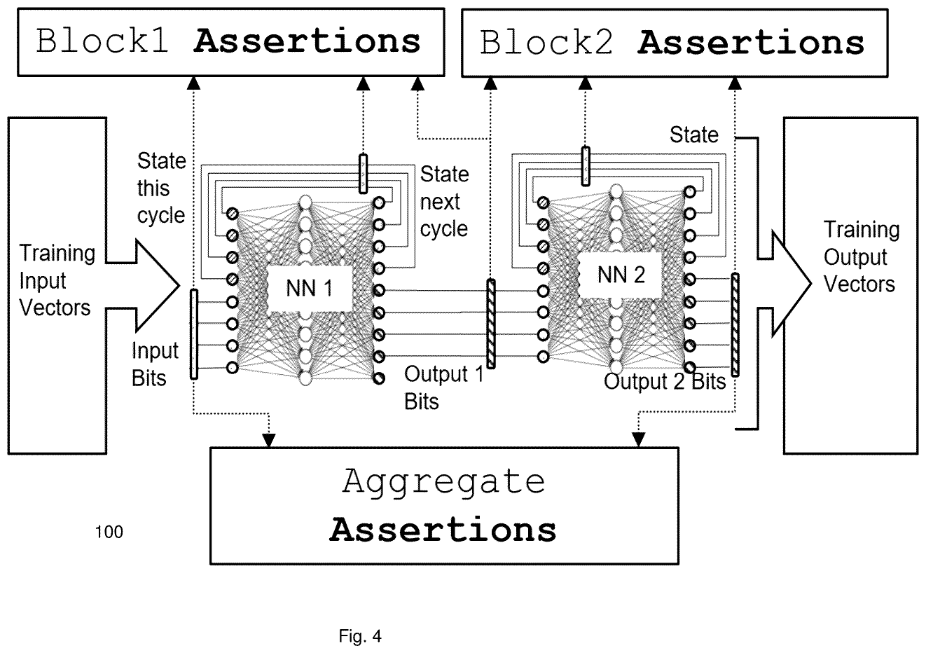

FIG. 4 illustrates a block diagram of an embodiment of an example model generator that has one or more inputs configured to receive inputs of formal descriptions of the expected behavior of that electronic block, written in a hardware assertion language in a format that an automated assertion checker tool can understand to be used as logical reasoning to constrain machine learning of that model from training data during training of that model to simulate the electronic block to be consistent with the logical reasoning.

Two generated models with neural network 1 and neural network 2 (NN1 and NN2) are composed to emulate electronic block1 and electronic block2. At each cycle, each model emulator predicts the next state and next output. The next input is provided as inputs in the system (lower left each block), and the predicted next state (upper right) is used provided as the input next state (upper left). Training vectors and assertions are satisfied at the block, subsystem, and system levels.

### Model Composition

The model generator 100 constructs the deep learning networks/architectures NN1 and NN2 from formal descriptions of the expected behavior of that electronic block, so composing the networks in the deep learning architecture is implemented directly by composing these terms. For understanding, let next1 and out1 predict the next state and output, respectively, for NN1, and similarly for next2 and out2 for NN2. Suppose that at cycle 1, block1 has state s1 and output o1, and block2 has state s2. Let ik be the input to block1 at cycle k. The states of NN1 over time are s1, next1 (i1,s1), next1(i2,next(i1,s1)), etc. NN1's outputs are o1, out1(i1,s1), out1(i2,next(s1), etc. NN2's output at cycle 2 is out2(o1,s2) and at cycle 3 is out2(out1(i1,s1),next2(o1,s2)). Thus, the model generator 100 simply writes these terms and then constructs the composed network for the example deep learning architecture shown in FIG. 4. The model generator 100 can reference the terms in the formal descriptions of an expected behavior of that electronic block about the aggregation of NN1 and NN2 as well as individual assertions about the blocks of NN1 and NN2, and all of these will be used to further train the models with the deep learning architecture emulating the electronic block (e.g. circuit). The additional constraints that might be known at the subsystem level can be used to improve the accuracy of the component networks.

Self-training and Compression. When the electronic blocks being emulated by the models are aggregated as shown NN1 and NN2, their parameters are updated based on the additional knowledge available at the subsystem level. There may also be additional training data available, if for example, the model generator 100 knows how the subsystem responds to given inputs without knowing how the individual blocks responded. The model generator 100 will use this additional learning to maintain accuracy in the aggregated system.

In general, the model generator 100 can reduce the complexity of the aggregated emulator by replacing it with a new emulator with fewer parameters (this will address speed and overtraining), trained at appropriate output intervals. This deep learning architecture trained to simulate an electronic block in the model will have an internal state vector, which is not a direct encoding of the registers of the component blocks but is learned by the deep learning architecture. Each new deep learning architecture that needs to be trained can be directly defined by the composition of the existing networks, such as:

$$NN ( x , s ) = out 2 ( out 1 ( x , next 1 ( s ) ) , next 2 ( s ) )$$

where s is the abstract state vector for the neural networks. S does not need to carry all of the information about these registers and next1 and next2 do not need to be highly accurate, but rather they only need to produce the information needed by next1 and next2 to generate the correct information. Knowledge might refer to the neural networks directly, and the model generator 100 may have training data directly for the neural networks as well, but the above composition initializes the neural networks to the level of information contained in the individual blocks.

### Protocol State Representation and Reasoning

Again, PSL is an example of a formal language that can be used to create behavioral assertions for electronic blocks and its subsystems. As an example, the PSL statement of the expected behavior of that electronic block:

$$( req ; ack ) \text{\vert =>} ( start ; busy {[}^{*} ] ; end )$$

asserts that if a req clock cycle is followed by an ack cycle, then this must be followed immediately by a start cycle, an arbitrary number of busy cycles, and finally an end cycle. The model generator 100 incorporates this behavioral knowledge. Let in and s be variables for the input and state vectors, respectively, at the start of the current clock cycle. Let next(in, s) generate the state vector for the next cycle and out(in, s) generate the outputs at the next cycle. Assume that req is an input event and that ack, start, busy, and end are all output signals of the block. The model generator 100 asserts that the req event holds for the input vector in by writing req (in). If x is an output vector, then the model generator 100 asserts that the ack event holds that vector by writing ack (x). Thus, next and out are functions that map tuples of vectors to vectors, while req and ack are Boolean predicates (functions that map vectors to values between 0 and 1). The PSL assertion above requires that if req is true of in and ack is true of the output generated by in when in the state s, then start needs to be true of the output produced from the next state after s, regardless of the input. This is formal descriptions of the expected behavior written in a hardware assertion language as:

$$( req ( in ) ∧ ack ( out ( in , s ) ) ] ‘ \text{-->} ’ start ( out ( x , next ( in , s ) ) )$$

where x ranges over any input vector. The model generator 100 compiles this logical reasoning into the neural network in which req, ack, start, out, and next are all component networks which output continuous values between 0 and 1. A (Boolean AND) and ‘-->’ (Boolean IF-THEN) are arithmetic operators that operate on continuous values and agree with standard semantics for values of 0 and 1. The asserted outputs a 1 when it is perfectly satisfied and a lower value when it is not completely satisfied. 1 is treated as the correct output value, and errors are backpropagated to improve network accuracy.

Learning Properties. As above, next and out are to be learned so as to fit the training data and the logical rules to constrain the machine learning of that model from training data. There are three ways that the other predicates can be implemented and inputted into the model generator 100. In the simplest case, the exact signal is known and can be defined by the engineer. For example, req might be true exactly when the 5th input bit is high, etc. Alternatively, the engineer might not know the encoding for a given predicate but might know its value on some or all of the training vectors. These vectors can be annotated with their properties and the model with the deep learning architecture can learn to predict these values. Finally, it is possible for the model with the deep learning architecture to learn predicates from scratch without any additional annotation of training vectors. This is generally possible when the data and logical rules have enough constraints to warrant the inference, and difficult cases require special learning techniques. A simple case would be to learn to recognize the busy state, given that the start and end states are known. If some of the predicates are simple enough, then it might be possible to learn the predicates from enough training vectors without any property annotations.

Disjunctive Reasoning. Machine Learning indirectly is a powerful but difficult task. At a given stage in learning, the model being trained might be 50% certain that the output at a given cycle is ‘ack’ and 50% certain that the output is ‘start.’ It is possible for the model being trained to get stuck in a local minimum and not find a solution. The local minimum becomes more likely as the number of possible solutions increases. The local minimum arises because the model generator 100 knows the solution must be exactly one from a set of choices, but standard techniques for machine learning prefer to assign a little value to each possibility rather than to choose one. The model generator 100 can introduce new adaptive techniques to enable learning in these situations. The model generator 100 is configured with logic to provide self-awareness to recognize when the model being trained is stuck in a local minimum and is not finding a solution. Once stuck, the model generator 100 will move to stochastic (rather than gradient-based) techniques to escape the local minimum and move to a different area of the search space. In addition, if the move to stochastic techniques does not work, then the model generator 100 can then randomly restart optimizations at the cost of training time.

The model generator 100 can apply a labeled loss function to a single labeled batch of data during training given both labeled data and the logical reasoning. The model generator 100 then runs many simulations (in parallel) for N steps using random inputs without any labels and computes the logic loss for the sequence generated. The total loss function is a weighted sum of the labeled loss and the logic loss. Backpropagation and optimization are done using this total loss function, so the system learns from both the labels and the logical reasoning at the same time.

The model generator 100 when generating and training the resulting model having a deep learning architecture to simulate an electronic block will apply a gradient-based (e.g. gradient descent) optimization to search directly for test vectors that violate requirements, speeding the discovery of design flaws without relying on random vectors to find flaws.

### Training Data

The formal knowledge that is compiled into the deep learning architecture (e.g. AI networks) provides a complex structure without requiring that each component within the structure to be simulated to be fully coded in RTL, reducing overall training data requirements.

Also, the constructed deep learning architecture is configured to learn from a combination of labeled training data along with raw data that is not labeled during the training to simulate the specific electronic block. The model generator 100 is configured to train the deep learning architecture to a threshold accuracy that agrees (e.g. 98% accuracy) with the formal descriptions of the expected behavior of that electronic block with a mixture of labeled training data examples that are merely half the amount or less compared to an amount of the unlabeled training data examples during the training to simulate the specific electronic block. Thus, the amount of the unlabeled training data examples used during the training to simulate the specific electronic block is at least twice the amount of labeled training data examples needed to train the deep learning architecture.

In an example problem, the model generated by the model generator 100 had images of digits that were presented in triples in which the third digit was always the sum of the first two digits modulo 10. When provided with knowledge of this structure, the model from the model generator learned to recognize digits from their images with 98% accuracy using only 100 labeled (and 49,900 unlabeled) images. Typically, standard neural networks not using the available knowledge requires 50,000 labeled images to achieve the same accuracy rather than 100 labeled images.

In another example, a model trained by the model generator 100 on a standard image-understanding problem, the model generator 100 performed equivalent to competing systems when training on only 4% as many labels. After adding taxonomic knowledge to classification problem sets from the literature, the model generator 100 improved on state-of-the-art performance by over 11 absolute percentage points. Thus, less labeled data is needed to learn from small labeled data sets when complemented with formal behavior specification.

In the context of electronic blocks training to simulate, for example, circuits, labeled data will include test vectors that have been run through RTL simulation so that the model generator 100 knows what the correct output vectors are, and the unlabeled data corresponds to random vectors for which the model generator 100 does not know correct outputs. However, obtaining labeled data requires simulation time and will necessarily be restricted, whereas unlabeled data is practically free.

The model generator 100 trains the deep learning architecture (e.g. neural networks) to satisfy input/output test vectors with known values but also backpropagates loss based on failure to satisfy the formal descriptions of the expected behavior. Thus, the model generator 100 is configured to backpropagate loss based on failure to satisfy the formal descriptions of the expected behavior during training of the deep learning architecture, which allows the deep learning architecture (e.g. neural network) to generalize beyond a small set of test vectors that may be available.

### The Model Generator'S Impact

The model generator 100 that automatically generates each emulator model with its deep learning architecture that has been trained to simulate a specific electronic block in order to decrease the amount of time required for testing and verification, increase the speed of operation of each emulator model, and increase the accuracy of each emulator model on data that was not used for training. An EDA tool using the model generator 100 to generate the one or more models will allow circuit designers to work more flexibly and innovate more rapidly.

The model generator 100 will greatly improve microelectronics engineering practices, providing a new type of EDA tool. A new system design will typically include many existing components but may also require several new components that still need to be designed and subsequently tested. Test vectors and behavioral assertions for each new component will eventually be constructed. In test-driven and behavior-driven development, these vectors and assertions are constructed as an initial step. Because the model generator 100's input requirements can be merely the test vectors and behavioral assertions, the emulator of the electronic block can be constructed before the component level composition of the circuit is specified. Because the model generator 100 develops its own state representation, behavioral assertions about the states of the component (such as a state machine model) can be emulated prior to determining how a state is represented in the component. This allows system-level testing for systems containing devices that have not yet been designed, greatly facilitating the ability of the engineer to simultaneously design new components and the resulting new system that will use the components. The model generator 100 and its generated models will also be used to detect inconsistencies between behavioral assertions and protocols, even without test data. The model generator 100 and its generated models can be used to search directly for test vectors that demonstrate these design flaws before any implementation using machine learning search techniques.

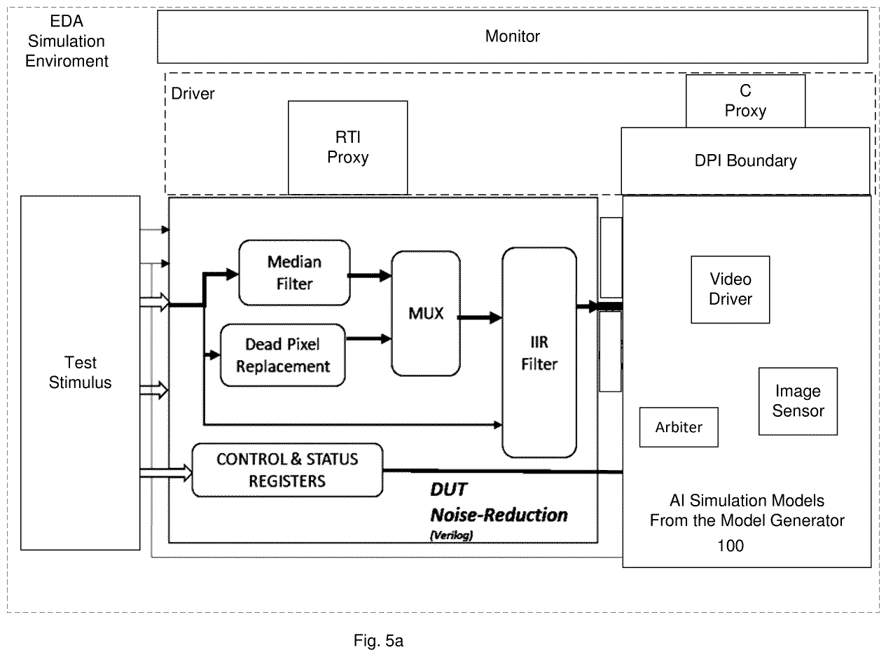

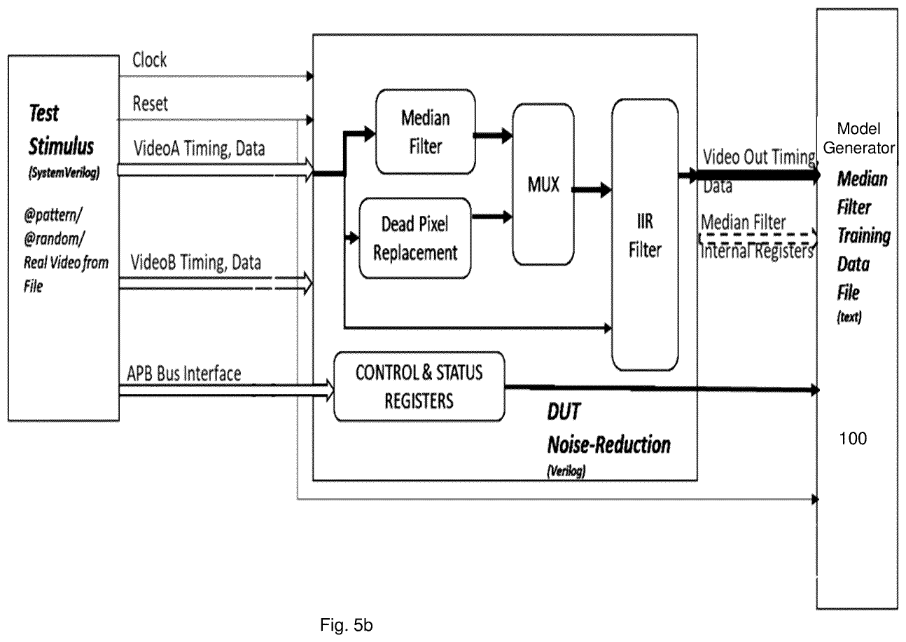

FIGS. 5a and 5b illustrate block diagrams of an embodiment of an example EDA tool configured to test and verify a device under test in a system containing the device under test and the electronic blocks to be simulated by the models generated by the model generator.

The model generator can use one or more deep learning architectures (e.g., neural networks) to simulate one or more electronic blocks in a system being tested with a DUT. In the EDA testing and verification environment, the DUT is simulated at RTL and the one or more generated models that each have a deep learning architecture to simulate their corresponding electronic block are simulated at a level of abstraction above RTL.

At a high level, the UVM Testbench framework is presented in FIG. 5a for the DUT of a Noise Reduction filter being tested with models from the model generator simulating an Arbiter, an Image sensor, etc. that are also in the system containing the Noise Reduction filter.

The deep learning architecture created in the model can be a neural network constructed and trained with the training data to simulate the electronic block, e.g. the arbiter. The electronic block to be simulated, e.g. the arbiter, is a representation of an individual electronic circuit within a system that contains a device under test to be tested and verified in an electronic design automation testing environment.

### Electronic Design Automation Tools

When designing a new digital circuit, application-specific integrated circuit, etc., the design needs to be tested in the context of the system in which it will be deployed, requiring simulation in an EDA environment of all other components/devices in the system.

Testing the DUT in the EDA environment generally involves (i) generating input signals to send to the DUT (or directly to its subsystems), (ii) capturing the output generated by the DUT (or any of its subsystems) in response to the inputs, and (iii) evaluating/verifying the correctness of the output. In the UVM framework, Agents are responsible for Driving (sending signals to) the DUT and Monitoring for observing signals from the DUT. A Scoreboard evaluates the correctness of the output. These agents control the evaluation. A UVM tool, such as Questa Prime, allows agents to drive devices/components which may be simulated either in RTL, in C, or another coding language, and the UVM tool allows any mixture of these simulators. The model generator can be used in a technique for using the UVM tool (e.g. Questa Prime) which allows the different devices in the system containing the DUT to function on different transaction boundaries by caching data. This caching impacts the wall-clock time of the simulation but does not disrupt the accurate simulation of the circuit clock that synchronizes communication within the circuit. The UVM tool (e.g. Questa Prime) interacts with C code through the Direct Programming Interface (DPI). Using this framework, the human designer can define a full system in RTL and measure its performance. However, with the UVM tool using the models from the model generator, the human designer can replace any of the RTL electronic blocks with a model having a deep learning architecture to simulate that electronic block coded in C that operates at a desired transaction scale to compare timing and accuracy information. The model that has a deep learning architecture to simulate an electronic block coded in C is developed through the AI based model generator, so they do not need to be written by the human engineer developing the new circuit as well as the generated models do not require the human engineer to understand the internal function of those blocks more than was required for the RTL simulation. Thus, at least the DUT and optionally one or more of the other electronic blocks in the system being tested with the DUT can be coded in RTL. The remainder of the electronic blocks in the system being tested with the DUT will be generated models from the model generator that have been trained to simulate that specific electronic block. In this example, the known, mature available devices, such as an Arbiter circuit, an Image Sensor circuit, etc., that have a well-defined interface interact with the rest of the test bench.

The Noise Reduction Filter can perform three kinds of filter operations namely a 3×3 median filter, a 3×3 dead pixel replacement and an IIR filter. The test stimulus will provide the input signal to those individual blocks and monitor and log the outputs. Multiple instances of the noise reduction filter will be used as DUTs to test/train on standalone filter operation. The DUT such as a Noise Reduction Filter simulated at RTL is connected to a layer of transactors (drivers, monitors, responders). These transactors communicate with the DUT and the models with the deep learning architecture trained to simulate the known, mature available devices, such as the Arbiter circuit and the Image Sensor circuit, at the pin level by driving and sampling DUT and model signals, and with the rest of the UVM testbench by passing transaction objects. They convert data between pins and transactions, i.e. from/to signal to/from transaction level.

### AI Deep Learning Architecture

In an example, a set of models each having a deep learning architecture, such as an Image Sensor circuit, an Arbiter circuit, a Video Driver, etc. can simulate all of the devices/electronic blocks outside of the DUT. An example model having a deep learning architecture uses a kernel size of 3 pixels by 3 pixels, a stride of 1, and padding of 1. This way the input to each layer of the deep learning architecture is the same size. Batch norm and a rectified linear unit (ReLU) are applied to the output of each convolutional layer other than the output layer in the deep learning architecture. There are 5 hidden convolutional layers in this example deep learning architecture. The numbers of output channels for these layers are 16, 32, 64, 32, and 16, respectively. The final layer always has a single output channel. Each model with the deep learning architecture (e.g. CNN) is generated by the model generator to accept, in this example, multiple frames as inputs.

Each model with the deep learning architecture can be trained by the model generator by first z-scaling all inputs and outputs. Each model with the deep learning architecture can be trained in, for example, PyTorch using the AdamW optimizer with a batch size of 32 and a learning rate of 0.001. The PyTorch's JIT compiler can be used to save the final model as TorchScript. A simple wrapper interface written in C++ can interface both with the QuestaPrime UVM environment and the model having a deep learning architecture trained to simulate an electronic block, enabling the AI models to run in the UVM environment.

The UVM verification framework allows an RTL coded device to be swappable with the model having a deep learning architecture trained simulate the device. Again, in an example, the model generator has trained the individual models simulating the electronic block to restrict the deep learning architecture/AI network to learn behavior consistent with the specified behavior of the electronic block being simulated (e.g. an Arbiter circuit).

Referring back to the transactors and layers of the UVM tool, the testbench layer above the transactor layer consists of components that interact exclusively at the transaction level, such as scoreboards, coverage collectors, stimulus generators, etc. All structural elements in a UVM testbench are extended from the uvm_component base class.

The lowest level of a UVM testbench is interface-specific. For each interface, the UVM provides a UVM Agent that includes the driver, monitor, stimulus generator (sequencer) and (optionally) a coverage collector. The Agent thus embodies all of the protocol-specific communication with the DUT and the models trained to simulate their electronic block. The Agent(s) and other design-specific components are encapsulated in a uvm_env environment component which is in turn instantiated and customized by a top-level uvm_test component.

The uvm_sequence_item—sometimes referred to as a transaction—is a uvm_object that contains the data fields necessary to implement the protocol and communicate with the DUT and the models trained to simulate their electronic block. The UVM Driver is responsible for converting the sequence_item(s) into “pin wiggles” on the signal-level interface to send and receive data to/from the DUT and the models trained to simulate their electronic block. The sequence_items are provided by one or more uvm_sequence objects that define stimulus at the transaction level and execute on the agent's uvm_sequencer component. The sequencer is responsible for executing the sequences, arbitrating between them and routing sequence items between the driver and the sequence.

The UVM Monitor is responsible for passively observing the pin-level behavior on the interface to the DUT and the models trained to simulate their electronic block, converting the pin-level behavior into sequence items and providing those sequence items to analysis components in the agent or elsewhere in the testbench such as coverage collectors or scoreboards. UVM Agents also have a configuration object that allows the test writer to control aspects of the agent as the testbench is assembled and executed. By providing a uniform interface to the testbench, a UVM Agent isolates the testbench and the UVM Sequence from details of the interface implementation. A sequence that provides data packets, for example, can be reused with different UVM Agents that may implement AHB, PCI, or other protocols. A UVM testbench will typically have one agent per interface to the DUT and the models trained to simulate their electronic block.

For a given design, the UVM Agents and other components are encapsulated in a uvm_env environment component, which is typically design-specific. Like an agent, an environment typically has a configuration object associated with it that allows the test to control aspects of the environment as well as to control the agents instantiated in the environment. Because environments are themselves UVM components, they can be assembled into a higher-level environment. As block-level designs are assembled into subsystems and systems, the block level UVM environment associated with the block may be reused as a component in the subsystem-level environment, which can itself be reused in the system-level testbench.

Once the EDA environment for the UVM has been defined, the uvm_test will instantiate, configure and build the environment, including customizing key aspects of the overall testbench, including:
choosing variations of components to be used in the environment,
choosing UVM sequences to be run either in the background or as the main portion of the test, and
defining configuration objects for the environment, sub-environment(s) (if any) and agent(s) in the testbench.

Note that the UVM environment captured all control signals and was able to propagate correctly while the deep learning architectures simulating their electronic block can ignore them entirely and merely populate the pixel data. This allowed for a substantial speedup with minimal effort in the AI design. The model generator can use, for example, this deep learning architecture simulation of digital circuits to improve speed up a time required to test novel new microelectronic systems while still in the design stage while maintaining current high levels of the design validation.

Again, EDA tool providers can use the model generator to reduce simulation times. EDA tools are often run on expensive FPGA machines (e.g. custom hardware) in order to maximize speed. Simulation time is one of the main bottlenecks in the development of digital circuits. The model generator reduces simulation times, reduces development costs, and time to market.

EDA tool providers can integrate the model generator into their tools. The model generator is configured to generate the one or more models that have been trained to simulate corresponding specific electronic blocks to cooperate with an EDA tool. Circuit designers (EDA tool users) will be indirect adopters. In some uses, the model generator trades off speed with accuracy, and circuit designers will need to design tests that are informative and effective even when simulation errors are made. The payoff for the circuit designers is faster time to market and lower development cost, but the risk is the initial slow-down from learning to use the new tools and the possibility of time wasted on misdiagnosed simulation errors. The payoff for the EDA tool providers is increased market demand, if their tools are shown to reduce development time. The circuit developers can use the EDA tools incorporating the model generator and/or the resulting models that are generated effectively to realize the time savings.

Note, current state-of-the-art tools only use the formal descriptions of the expected behavior after the simulation and testing of the DUT in conjunction with these generated models to detect errors. The model generator requires the input of formal assertions input in advance of the UVM simulation with the DUT and the generated models.

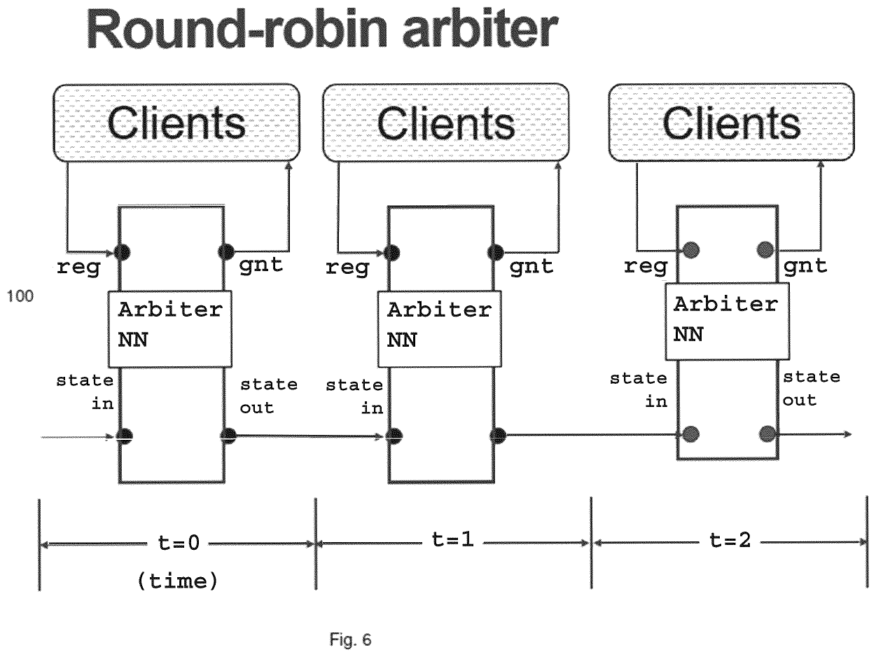

FIG. 6 illustrates a block diagram of an embodiment of an example model having a deep learning architecture to simulate an electronic block of a round robin Arbiter circuit.

A top-level System Verilog testbench can consist of the round robin Arbiter circuit as the DUT, a test stimulus supplied into the DUT, and a DUT data capture into a file. The round-robin Arbiter circuit as the DUT can be an open-source1 System Verilog file. The model generator 100 can use ModelSim-DE to compile and run the simulation. The test stimulus can consist of clock and reset generation, random request generation by clients that are held until a grant is received by the DUT, and a file write task that captures the rising edge of clock, the DUT inputs (reset, stall, clients request), the outputs (clients grant) and the DUT internal state (before issuing the final grant) to a text file. The captured data can be used as training data for and/or with the model with the neural network to simulate the round robin Arbiter circuit.

The Arbiter block interacts with a set of N clients. Each client sends a 1-bit signal to the Arbiter at every clock cycle: 0 indicating no request, and 1 indicating a request, forming N input signals named req0, req1, . . . , reqN−1. Each cycle, the Arbiter generates output signals gnt0, gnt1, . . . , gntN−1. The full Arbiter has two control inputs for resetting and pausing. The Arbiter also has two registers, named prev_grant and new_grant. Again, in order to minimize complexity of learning for this Arbiter, the model generator 100 makes use of the formal knowledge assertion that proper functionality of the Arbiter depends on the correct value of new_grant at the start of each clock cycle, but that the value of prev_grant can be ignored. For this reason, the model generator 100 logged only new_grant when simulating the Arbiter.

The model generator 100 begins by formalizing the language of the formal descriptions of an expected behavior. The open-source Arbiter supplies the following System Verilog Assertion:

$$request [ 4 ] \text{\vert ->} \#\# [ 0 : 7 ] grant [ 4 ]$$

This syntax says that if bit 4 of the request signal is high, then there is a time 0 to 7 time-steps later at which bit 4 of the grant signal is high. The theory module of the model generator 100 takes this in and uses standard first order logic syntax, so the model generator 100 needs a relation req(t, c) to indicate a request from client c at time t and a relation gnt(t, c) to indicate a grant to client c at time t. The model generator 100 uses standard quantifiers “for all” and “there exists” for quantifiers, and always uses defined domains for variables. The model generator 100 defines the domain Clients to be {0, 1, . . . , 7} and the domain Time to be {0, 1, . . . , Tmax}. The model generator 100 can state the above assertion as:

For every client c, for every time point t1, if req(t1, c) and t1ξTmax−7 then there exists t2 in Time such that gnt(t2, c) and t1ξt2ξt1+7

$$( ∀ c \text{:} Clients ) ( ∀ t ! \text{:} Time ) [ ( req ( t ! , c ) ∧ t ! \leq {T}^{″} \#\$ - 7 )$$

$$( ∃ t \text{:} Time ) ( gnt ( t , c ) ∧ t ! \leq t \% ∧ t \% \leq t ! + 7 ) ]$$

$$( A \# c \text{:} Clients ) ( A \# t 1 : T ) ( ( t 1 < num\_steps - 7 \& req ( t 1 , c ) )$$

$$-> ( E \# t 2 : T ) ( t 1 <= t 2 \& t 2 <= t 1 + 7 \& gnt ( t 2 , c ) ) )$$

The parentheses around the quantifiers are written above to help the reader map to the original logic notation, but they can be omitted in the model generator 100. The model generator 100 defines:

$$DEFINE grantInTime = E \# t 2 : T ( t 1 <= t 2 \& t 2 <= t 1 + 7 \& gnt ( t 2 , c ) )$$

$$DEFINE reqInRange = t 1 < num\_steps - 7 \& req ( t 1 , c )$$

DEFINE gnt_in_7_cycles=A #c:Clients A #t1:T (reqInRange->grantInTime)

thus obtaining the above logical reasoning, now named “gnt_in_7_cycles”.

The model generator 100 can be implemented in Pytorch and interoperates with neural networks defined in Pytorch. All data structures are Pytorch tensors, so the logical reasoning above needs to be applied to input tensors. The model generator 100 can chose to represent the req signals as a tensor X to be input to the Arbiter simulator and the gnt signals as a tensor Y generated by the Arbiter simulator. The outputs Y are neural network outputs, which are continuous valued. The logical reasoning such as gnt_in_7_cycles is applied to the tensors X and Y by defining a function index (z, t, c) to pull out time step t for client c from tensor z.

Each tensor represents a fixed number of time steps for the system to be run, say 20. This allows the model generator 100 to evaluate the system over a period of 20 steps. To do this, the model generator 100 is told that num_steps=20, that T is the tensor [0, . . . , 19], and that Clients is the tensor [0 . . . 7]. X and Y become arguments to the network created by the model generator 100, so the model generator 100 constructs X and Y by running the simulation tool just for 20 steps without training and then apply the deep learning network to X and Y. Note, when X and Y perfectly satisfy specified behavior/function of the electronic block being simulated such as satisfying gnt_in_7_cycles, then the deep learning architecture/network generates a loss value of 0.0. The loss value grows without bound as X and Y are increasingly far away from the satisfying the specified behavior/function of the electronic block being simulated e.g. gnt_in_7_cycles. The Y tensor has dependencies on the Arbiter model parameters that are being learned, so backpropagation of the loss function is provided through the standard Pytorch methods.

Another condition that the Arbiter must satisfy is that there be exactly one grant at every time point. Classical logical representations use “there exists” to mean that there exists at least one item, but there is not standard syntax and semantics for counting a specific number of objects. The model generator 100 can implement counting exactly one bit. The model generator 100 can include the additional knowledge about the Arbiter's behavior: All grants other than to client 0 must be made to a client with an active request. When there are no requests, grant to 0. Always grant to request when there is one. Always grant to the next highest requestor (c2) after the most recent grant (to c1) if any. When no requestor is higher than the most recent grant, grant the lowest current requestor.

Putting these rules together with the ones stated above, the model generator 100 can state the example theory of the Arbiter. When the model generator 100 always makes exactly one grant and if the model generator 100 never grants to a client other than 0 that isn't making a request, then necessarily the model generator 100 will always grant to 0 when no client is making a request. When the model generator 100 follows the logical reasoning about granting to the next highest if there is one and granting to the least otherwise, then the generated model is guaranteed to make every grant with 7 cycles of the request. Because these constraints are consistent, this redundancy is not expected to hurt learning.

An example deep learning architecture to simulate the electronic block of the Arbiter can be composed as follows. The neural network of the deep learning architecture can take in 16 input bits (8 req signal and 8 state) and produce 16 output bits (8 gnt signal and 8 state). As with any machine learning problem, the model generator 100 wants to compose an architecture which is limited as possible while still being able to learn a solution. This prevents overtraining, allowing for favorable generalization. The inputs signal_in and state_in are supplied. The state map can be a special transformation that the model generator 100 described below. Act_inA and Act_inB indicate the possibility of applying activation functions to these inputs. The network can include a fully connected layer FC1 between the inputs and the first hidden layer, with activation Act1. The first hidden layer has 16 nodes, so FC1 is a 16×16 matrix to be learned. FC2 and Act2 can be a second full connected layer and activation function, this time a 16×8 matrix as the next hidden layer has only 8 nodes. Finally, the network generates the 16 output values. Act_outA and Act_outB suggest the possibility that the activation applied to the signal output might be different from that applied to the state output.

### Activation Functions

The classical backpropagation neural network uses the sigmoid activation function at every layer. The output of the sigmoid is always between 0 and 1, and in typical use the goal is to produce either a 0 or a 1, with intermediate values available to enable learning. In the context, the model generator 100 will call the outputs of sigmoid functions bits. The input to the sigmoid activation (the output of the matrix multiplication) is called a logit. Logits can be any floating point value. Sigmoid maps 0 to 0.5, all negative logits to bits less than 0.5, and all positive logits to bits greater than 0.5. the model generator 100 need to decide whether to represent the output state values as logits or as bits. If they are bits, then the model generator 100 will have a nested application of the sigmoid function. Once the nesting is deep enough, then the gradient vanishes and learning cannot take place, which is one of the reasons that the neural networks would not be made too “deep” when the sigmoid function was the main activation function available. If the model generator 100 allows the outputs to be logits, then successive applications of the NN can cause the size of the logit to grow without bound, causing instability in longer sequences. The model generator 100 can chose to use a logit representation but could have used the bit representation. Since the model generator 100 focused on shorter sequences (4 steps rather than 20 or 50), so that the vanishing gradient might not be a problem.

The formal descriptions of the expected behavior as constraints, via System Verilog assertions, tells the model generator 100 that in this electronic block of an Arbiter, for example, 1) each client will be granted a requested access within n clock cycles of the request, and 2) the documentation tells us that exactly one grant is given on each clock cycle. Using these formal constraints in the model generator 100, the model generator 100 was able to train the same NN architecture to 80% accuracy with an 8× reduction in the amount of labeled training data required without the model generator 100.

Note, the model generator 100 and emulation in its generated models is not a Formal Methods approach. But rather, emulation in the generated models from the model generator 100 is based on machine learning from training data. Formal Methods techniques typically require the full formal specification of all behavior of a circuit (to be emulated) in order to prove correctness. Instead, the model generator 100 and emulation in its generated models uses whatever partial formal specification is available and does not require more. The information is used to guide the machine learning, so there is never a requirement for completeness. Since each generated model machine learns and does not attempt to generate proofs, it does not require supervised guidance from users during the implementation of that formal method, like formal methods do.

The model generator 100 constructs, for example, a neural network that will be capable of simulating the devices/components in the digital circuit much faster than can be achieved by RTL simulation. The models have a deep learning architecture that can accomplish this by using larger transactions than the single clock cycle used by RTL and that might introduce some errors. A tradeoff between speed and accuracy will allow many cycles of testing to be completed much more quickly, requiring only occasional testing in the error-free RTL system.

The model generator 100 uses formal knowledge which is already available about the devices/components in the electronic block (e.g. digital circuit) to be simulated in order to reduce the amount of training data required for training the generated model having the deep learning architecture while maintaining high accuracy. Formal knowledge about the behavior and functionality of an electronic block, e.g. digital circuit, is usually plentiful in form of assertions and specifications. These specifications are typically checked during the simulation of an electronic block, for example, i) an electronic component, ii) an electronic circuit, iii) an electronic subsystem, iv) a system on a chip, and v) an integrated circuit chip, to verify that the electronic block being simulated satisfies them. The model generator 100 creates the model via using these specifications to provide a feedback signal to the deep learning architecture within that model. Typically, in prior techniques, these specifications are seen as purely discrete and as having been passed or failed, while deep learning requires continuous values in order to backpropagate. The model generator 100 generating the model having a deep learning architecture to simulate an electronic block bridges this gap.

The techniques described in this disclosure may be implemented, at least in part, in hardware, software, firmware, or any combination thereof. For example, various aspects of the described techniques may be implemented within one or more processors, including one or more microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure. A module may be implemented in software stored in a memory and executed by one or more processors, in electronic hardware such as logic circuits, and any combination of both.

### Computing Systems

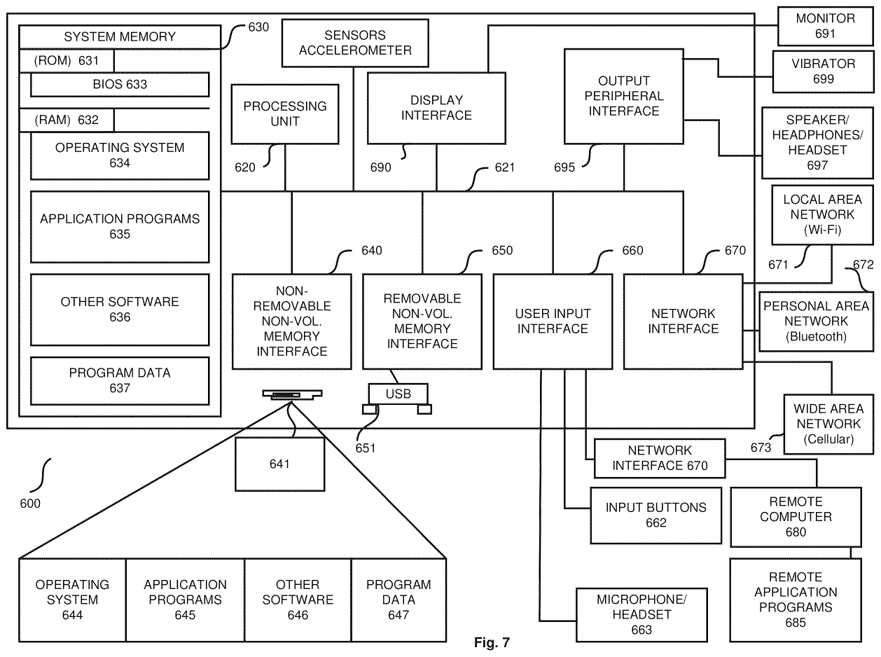

FIG. 7 illustrates a diagram of an embodiment of a computing device that can be a part of the systems associated with the device and its associated modules and the machine learning architecture discussed herein. The computing device 600 may include one or more processors or processing units 620 to execute instructions, one or more memories 630-632 to store information, one or more data input components 660-663 to receive data input from a user of the computing device 600, one or more modules that include the management module, a network interface communication circuit 670 to establish a communication link to communicate with other computing devices external to the computing device, one or more sensors where an output from the sensors is used for sensing a specific triggering condition and then correspondingly generating one or more preprogrammed actions, a display screen 691 to display at least some of the information stored in the one or more memories 630-632 and other components. Note, portions of this system that are implemented in software 644, 645, 646 may be stored in the one or more memories 630-632 and are executed by the one or more processors 620.

As discussed, the device and its associated modules, the generated models and the machine learning architecture, and the EDA tools can be implemented with aspects of the computing device. The modules and/or models can work with one or more processors to execute instructions and a memory to store data and instructions.

The system memory 630 includes computer storage media in the form of volatile and/or nonvolatile memory such as read-only memory (ROM) 631 and random access memory (RAM) 632. These computing machine-readable media can be any available media that can be accessed by computing system 600. By way of example, and not limitation, computing machine-readable media use includes storage of information, such as computer-readable instructions, data structures, other executable software, or other data. Computer-storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other tangible medium which can be used to store the desired information and which can be accessed by the computing device 600. Transitory media such as wireless channels are not included in the machine-readable media. Communication media typically embody computer readable instructions, data structures, other executable software, or other transport mechanism and includes any information delivery media.

The system further includes a basic input/output system 633 (BIOS) containing the basic routines that help to transfer information between elements within the computing system 600, such as during start-up, is typically stored in ROM 631. RAM 632 typically contains data and/or software that are immediately accessible to and/or presently being operated on by the processing unit 620. By way of example, and not limitation, the RAM 632 can include a portion of the operating system 634, application programs 635, other executable software 636, and program data 637.

The computing system 600 can also include other removable/non-removable volatile/nonvolatile computer storage media. By way of example only, the system has a solid-state memory 641. The solid-state memory 641 is typically connected to the system bus 621 through a non-removable memory interface such as interface 640, and USB drive 651 is typically connected to the system bus 621 by a removable memory interface, such as interface 650.

A user may enter commands and information into the computing system 600 through input devices such as a keyboard, touchscreen, or software or hardware input buttons 662, a microphone 663, a pointing device and/or scrolling input component, such as a mouse, trackball or touch pad. These and other input devices are often connected to the processing unit 620 through a user input interface 660 that is coupled to the system bus 621, but can be connected by other interface and bus structures, such as a parallel port, game port, or a universal serial bus (USB). A display monitor 691 or other type of display screen device is also connected to the system bus 621 via an interface, such as a display interface 690. In addition to the monitor 691, computing devices may also include other peripheral output devices such as speakers 697, a vibrator 699, and other output devices, which may be connected through an output peripheral interface 695.

The computing system 600 can operate in a networked environment using logical connections to one or more remote computers/client devices, such as a remote computing system 680. The remote computing system 680 can a personal computer, a mobile computing device, a server, a router, a network PC, a peer device or other common network node, and typically includes many or all of the elements described above relative to the computing system 600. The logical connections can include a personal area network (PAN) 672 (e.g., Bluetooth®), a local area network (LAN) 671 (e.g., Wi-Fi), and a wide area network (WAN) 673 (e.g., cellular network), but may also include other networks such as a personal area network (e.g., Bluetooth®). Such networking environments are commonplace in offices, enterprise-wide computer networks, intranets and the Internet. A browser application may be resonant on the computing device and stored in the memory.

When used in a LAN networking environment, the computing system 600 is connected to the LAN 671 through a network interface 670, which can be, for example, a Bluetooth® or Wi-Fi adapter. When used in a WAN networking environment (e.g., Internet), the computing system 600 typically includes some means for establishing communications over the WAN 673. With respect to mobile telecommunication technologies, for example, a radio interface, which can be internal or external, can be connected to the system bus 621 via the network interface 670, or other appropriate mechanism. In a networked environment, other software depicted relative to the computing system 600, or portions thereof, may be stored in the remote memory storage device. By way of example, and not limitation, the system has remote application programs 685 as residing on remote computing device 680. It will be appreciated that the network connections shown are examples and other means of establishing a communications link between the computing devices that may be used.

As discussed, the computing system 600 can include mobile devices with a processing unit 620, a memory (e.g., ROM 631, RAM 632, etc.), a built in battery to power the computing device, an AC power input to charge the battery, a display screen, a built-in Wi-Fi circuitry to wirelessly communicate with a remote computing device connected to network.

It should be noted that the present design can be carried out on a computing system such as that described with respect to shown herein. However, the present design can be carried out on a server, a computing device devoted to message handling, or on a distributed system in which different portions of the present design are carried out on different parts of the distributed computing system.

In some embodiments, software used to facilitate algorithms discussed herein can be embedded onto a non-transitory machine-readable medium. A machine-readable medium includes any mechanism that stores information in a form readable by a machine (e.g., a computer). For example, a non-transitory machine-readable medium can include read-only memory (ROM); random access memory (RAM); magnetic disk storage media; optical storage media; flash memory devices; Digital Versatile Disc (DVD's), EPROMs, EEPROMs, FLASH memory, magnetic or optical cards, or any type of media suitable for storing electronic instructions.

Note, an application described herein includes but is not limited to software applications, mobile applications, and programs that are part of an operating system application. Some portions of this description are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like. These algorithms can be written in a number of different software programming languages such as C, C+, HTTP, Java, Python, or other similar languages. Also, an algorithm can be implemented with lines of code in software, configured logic gates in software, or a combination of both. In an embodiment, the logic consists of electronic circuits that follow the rules of Boolean Logic, software that contain patterns of instructions, or any combination of both. Any portions of an algorithm implemented in software can be stored in an executable format in portion of a memory and is executed by one or more processors. In an embodiment, a module can be implemented with electronic circuits, software being stored in a memory and executed by one or more processors, and any combination of both.

It should be borne in mind, however, that all of these and similar terms are to be associated with the appropriate physical quantities and are merely convenient labels applied to these quantities. Unless specifically stated otherwise as apparent from the above discussions, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers, or other such information storage, transmission or display devices.

Many functions performed by electronic hardware components can be duplicated by software emulation. Thus, a software program written to accomplish those same functions can emulate the functionality of the hardware components in input-output circuitry.

References in the specification to “an embodiment,” “an example”, etc., indicate that the embodiment or example described may include a particular feature, structure, or characteristic, but every embodiment may not necessarily include the particular feature, structure, or characteristic. Such phrases can be not necessarily referring to the same embodiment. Further, when a particular feature, structure, or characteristic is described in connection with an embodiment, it is believed to be within the knowledge of one skilled in the art to affect such feature, structure, or characteristic in connection with other embodiments whether or not explicitly indicated.

While the foregoing design and embodiments thereof have been provided in considerable detail, it is not the intention of the applicant(s) for the design and embodiments provided herein to be limiting. Additional adaptations and/or modifications are possible, and, in broader aspects, these adaptations and/or modifications are also encompassed. Accordingly, departures may be made from the foregoing design and embodiments without departing from the scope afforded by the following claims, which scope is only limited by the claims when appropriately construed.

What is claimed is:

1. An apparatus, comprising:
a model generator with one or more inputs configured to receive inputs of formal descriptions of an expected behavior of an electronic block, where the model generator is configured to generate one or more models, where each generated model has a deep learning architecture to simulate an electronic block based upon the formal descriptions of an expected behavior of the electronic block, where the electronic block consists of at least one of i) an electronic component, ii) an electronic circuit, iii) an electronic subsystem, iv) a system on a chip, and v) an integrated circuit chip, where any portion of the model generator and generated models that are implemented with software, then the software is stored on one or more non-transitory machine readable mediums and are to be executed by one or more processors.

2. The apparatus of claim 1, where the deep learning architecture created in the model is a neural network constructed and trained with training data to simulate the electronic block.

3. The apparatus of claim 1, where the electronic block to be simulated is a representation of an individual electronic circuit within a system that contains a device under test to be tested and verified in an electronic design automation testing environment.

4. The apparatus of claim 1, where the model generator is configured to construct the deep learning architecture to simulate the electronic block based on the formal descriptions of the expected behavior rather than needing a formal specification on a full architecture making up the electronic block, which is configured to cause a verification of a device under test to occur in less time than the verification of the device under test would take with the full architecture making up the electronic block.

5. The apparatus of claim 1, where the model generator is further configured to train the model with the deep learning architecture to simulate the electronic block using the formal descriptions of an expected behavior of that electronic block as logical reasoning to constrain machine learning of that model from training data during training of that model to simulate the electronic block to be consistent with the logical reasoning.

6. The apparatus of claim 5, where the model generator is configured to generate the one or more models, where the models have been trained to simulate corresponding specific electronic blocks to cooperate with an electronic design automation tool.

7. The apparatus of claim 5, where the model generator is configured to cooperate with an electronic design automation tool to test and verify a device under test in a system containing the device under test and the one or more models that have been trained to simulate the corresponding specific electronic blocks.

8. The apparatus of claim 1, where the device under test is simulated at RTL and the one or more generated models that each have the deep learning architecture to simulate the electronic block are simulated at a level of abstraction above RTL.

9. The apparatus of claim 1, where the model generator further comprises:
a theory module configured to receive as input the formal descriptions of the expected behavior of that electronic block expressed in first order logic elements and then encode and send the encoded formal descriptions of the expected behavior of that electronic block to a model building module in the model generator to use machine learning to discover distributed vector representations of a meaning associated with information in the formal descriptions of the expected behavior and generate the deep learning architecture.

10. The apparatus of claim 5, where the model generator is configured to train the deep learning architecture to a threshold accuracy that agrees with the formal descriptions of the expected behavior of that electronic block with a mixture of labeled training data examples and unlabeled training data examples, where an amount of unlabeled training data examples during the training to simulate the specific electronic block is at least twice the amount of labeled training data examples needed to train the deep learning architecture.

11. The apparatus of claim 5, where the constructed deep learning architecture is configured to learn from a combination of labeled training data along with unlabeled training data during the training.

12. The apparatus of claim 5, where the model generator is configured to backpropagate loss based on failure to satisfy the formal descriptions of the expected behavior during the training of the deep learning architecture, which allows the deep learning architecture to generalize beyond a set of test vectors that may be available.

13. A non-transitory machine-readable medium, which stores further instructions in the executable format by the one or more processors to cause operations as follows, comprising:
using a model generator with one or more inputs to receive inputs of formal descriptions of an expected behavior of an electronic block, where the model generator is configured to generate one or more models, where each generated model has a deep learning architecture to simulate an electronic block based upon the formal descriptions of an expected behavior of the electronic block, where the electronic block consists of at least one of i) an electronic component, ii) an electronic circuit, iii) an electronic subsystem, iv) a system on a chip, and v) an integrated circuit chip.

14. The non-transitory machine-readable medium of claim 13, where the deep learning architecture created in the model is a neural network constructed and trained with training data to simulate the electronic block.

15. The non-transitory machine-readable medium of claim 13, where the electronic block to be simulated is a representation of an individual electronic circuit within a system that contains a device under test to be tested and verified in an electronic design automation testing environment.

16. The non-transitory machine-readable medium of claim 13, further comprising:
using the model generator to construct the deep learning architecture to simulate the electronic block based on the formal descriptions of the expected behavior rather than needing a formal specification on a full architecture making up the electronic block, which causes a verification of a device under test to occur in less time than the verification of the device under test would take with the full architecture making up the electronic block.

17. The non-transitory machine-readable medium of claim 13, further comprising:
using the model generator to train the model with the deep learning architecture to simulate the electronic block using the formal descriptions of an expected behavior of that electronic block as logical reasoning to constrain machine learning of that model from training data during training of that model to simulate the electronic block to be consistent with the logical reasoning.

18. The non-transitory machine-readable medium of claim 17, further comprising:
using the model generator to generate the one or more models, where the models have been trained to simulate corresponding specific electronic blocks to cooperate with an electronic design automation tool.

19. The non-transitory machine-readable medium of claim 17, further comprising:
using the model generator to cooperate with an electronic design automation tool to test and verify a device under test in a system containing the device under test and the one or more models that have been trained to simulate the corresponding specific electronic blocks, where the device under test is simulated at RTL and the one or more generated models that each have the deep learning architecture to simulate the electronic block are simulated at a level of abstraction above RTL.

20. A method for simulating one or more electronic blocks, comprising:
using a model generator with one or more inputs to receive inputs of formal descriptions of an expected behavior of an electronic block, where the model generator is configured to generate one or more models, where each generated model has a deep learning architecture to simulate a first electronic block based upon formal descriptions of the expected behavior of the first electronic block, where the first electronic block consists of at least one of i) an electronic component, ii) an electronic circuit, iii) an electronic subsystem, iv) a system on a chip, and v) an integrated circuit chip.
